(19) United States
(12) Patent Application Publication
(10) Pub. No.: US 2010/0181465 A1
(43) Pub. Date: Jul. 22, 2010

(54) Snapshot mode active pixel sensor

(75) Inventor: Eric R. Fossum, Pasadena, CA (US)

Correspondence Address: Law Office of Scott C Harris Inc, PO Box 1389, Rancho Santa Fe, CA, 92067, US

(73) Assignee: FORZA SILICON, INC

(21) Appl. No.: 12/689,322

(22) Filed: Jan. 19, 2010

Related U.S. Application Data
(60) Provisional application No. 61/145,690, filed on Jan. 19, 2009.

(51) Int. Cl. H01L 31/113; H01L 31/09

(52) U.S. Cl. 250/214.1; 250/214 R

(57) ABSTRACT

A snapshot pixel device with an active reset that operates in charge mode.

This application claims priority from provisional No. 61/145,690, filed Jan. 19, 2009, the disclosure of which is herewith incorporated by reference.

### BACKGROUND

CMOS image sensors are known.

An active pixel sensor is disclosed in U.S. Pat. No. 6,744,068. In an active pixel sensor of this type, charge is accumulated in a photoreceptors, e.g., the area under a photogate. The charge is transferred from the photogate to a floating diffusion node, and to a source follower output amplifier. The output amplifier drives a voltage signal across a signal line e.g. a column line.

In a column parallel device, rows of pixels are read out sequentially as the pixels in a row drive their respective column lines. This is for example described in U.S. Pat. No. 7,369,166. After row has been completely read-out, some other row can be selected for reset. The row that is selected for reset is in general not the next row in the read-out sequence. Therefore, the reset row has a shortened integration time relative to the frame as a whole.

The cycle may continue with the next row being read out. When the next row is read and the process continues, the result is a so-called rolling shutter effect.

The rolling shutter can cause imaging artifacts. For example, it can distort objects relative motion within the image frame, and cause a “smearing” effect.

A snapshot pixel image sensor integrates all pixels simultaneously for a period less than the frame period. Several different techniques have been proposed for implementing such a snapshot sensor, for example see U.S. Pat. Nos. 6,486,503 and 7,388,239. In the case of '503, multiple high efficiency charge transfers are required. '239 introduces kTC noise into the readout of the charge storage element. This allows all pixels to be integrated simultaneously for a period less than the frame readout.

### SUMMARY

The present application reduces a need for multiple high efficiency charge transfers and still maintains the suppression of kTC noise in a pixel sensor that can integrate all pixels simultaneously for a period less than the complete frame period.

### BRIEF DESCRIPTION OF THE DRAWINGS

In the Drawings:

FIGS. 1A and 1B show embodiments with photogates;

FIG. 2 show an embodiment with a junction photogate;

FIG. 3 shows an alternative barrier layer;

FIG. 4 shows an embodiment using a subcollector;

FIG. 5 shows an embodiment using a collector and barrier; and Figure shows an embodiment with dual barriers.

### DETAILED DESCRIPTION

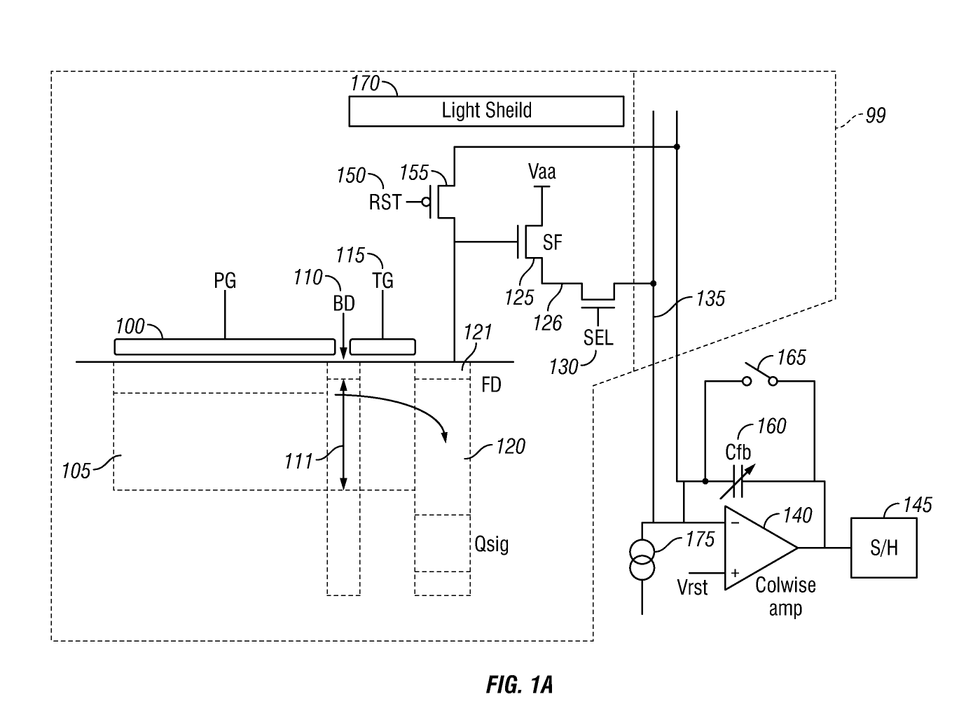

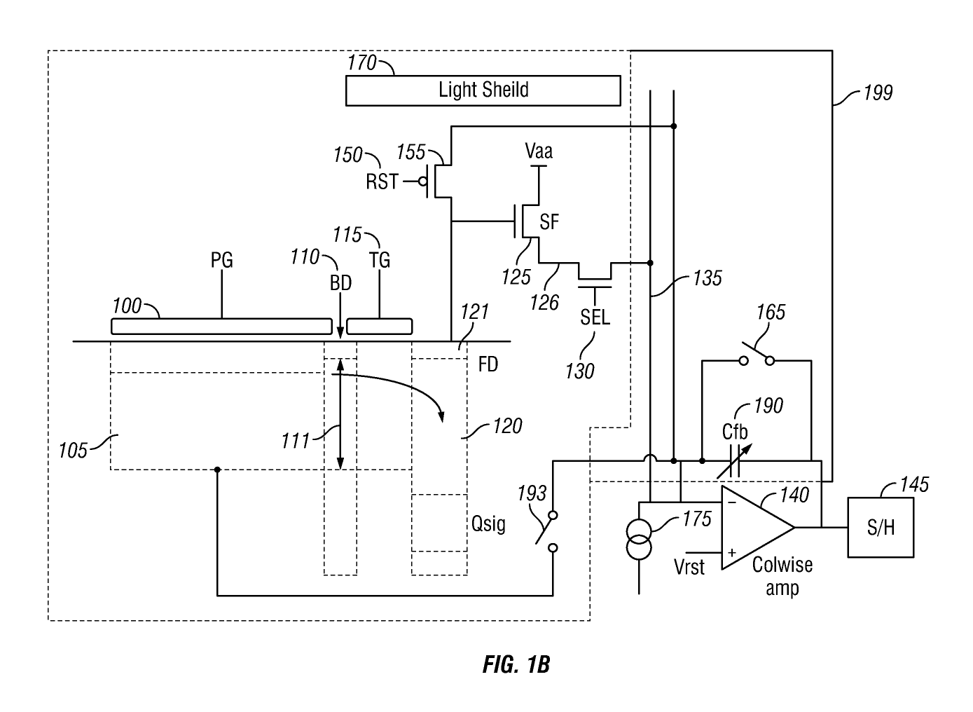

An embodiment is shown in FIG. 1A. A pixel 99 has individual components, and items outside the pixel are shared among multiple pixels in an array of pixels. According to this embodiment, a photogate 100 receives photoaccumulated charge and maintains that charge in a charge well 105. A controllable diffusion barrier 110 can be raised and lowered in potential shown as 111. When the diffusion barrier is raised to its top position, it blocks the transfer of the charge from the photogate well 105. The barrier 110 can be lowered by appropriate control of the transfer gate 115 to transfer the charge into the floating diffusion area 120.

The node 121 of floating diffusion 120 is connected to the base of the source follower transistor 125 which buffers the output signal. A pixel select transistor 130 uses a select line which is brought active to transfer the voltage from the source follower 125 to the read-out line 135.

A resettable column amplifier 140 drives a sample and hold circuit 145.

The embodiments use feedback to reset the charge on the floating diffusion to a nominal reset level. The use of this feedback forms a portion of the feedback loop, operating to reduce the KTc noise, since the reset is based on the amount of sampled charge.

In operation, signal photocarriers are integrated under the photogate PG. At the end of the integration period, the carriers are transferred by the transfer gate by pulsing the transfer gate high, or reducing the voltage on the photogate terminal.

The photo generated carriers are transferred to the floating diffusion 120. The time when this happens, called T1, marks the beginning of a frame cycle. The photogate and transfer data are then returned to their integrating levels, to again receive photo generated charge. While the photogate is integrating the charge from a next cycle (or ready to integrate), the charge from the previous cycle is held in the floating diffusion. The source follower SF 125 buffers the signal. The voltage indicative of the value in FD is presented at its output node 126.

The photogenerated charge is sampled from the floating diffusion by selecting a row or pixel of the sensor using the SEL signal.

A charge mode trans-impedance amplifier 175 can be shared among a number of different pixels. This amplifier outputs an amount of charge proportional to its input voltage from the readout of the pixel value. Each pixel is activated to use the trans-impedance amplifier by the select signal.

The read value is applied to amplifier 140, the other input of which receives the reset value Vrst. The output of the amplifier is a feedback voltage which is driven through the rest FET 155 by selecting the reset level RST.

This feedback value causes the output of the source follower transistor 125 to become equal to the reset level Vrst. The amount of charge that is required to maintain the output of the source follower at that level is integrated on the feedback capacitor 160. When RST is released, this charge level appears as a change in voltage at the output of the amplifier 140, and is then sampled and held by sample and hold circuit 145 as the readout value for the pixel. However, the floating diffusion has been consistently reset to the reset level Vrst, so that each floating diffusion is always actively reset to this value. This prevents stray charge in the components from causing KTc noise.

The feedback capacitor 160 can then be reset by a switch 165. This can zero out any voltage across the feedback resistor.

Well known techniques can be used to reduce the fixed pattern noise due to threshold variations in source follower. For example, this can be removed by digital techniques or off chip. Another embodiment may use a switched capacitor to null the column wise amplifier outputs

According to another embodiment in FIG. 1B, the feedback capacitor 190 is moved into the pixel 199, and can be used for both integration capacitance and also as the feedback capacitor. A switchable line 193 selectively connects the capacitor to the photogate area 105. This provides additional integration capability, however, trades off at the expense of additional pixel area and complexity.

FIGS. 1A and 1B are embodiments with MOS photogates.

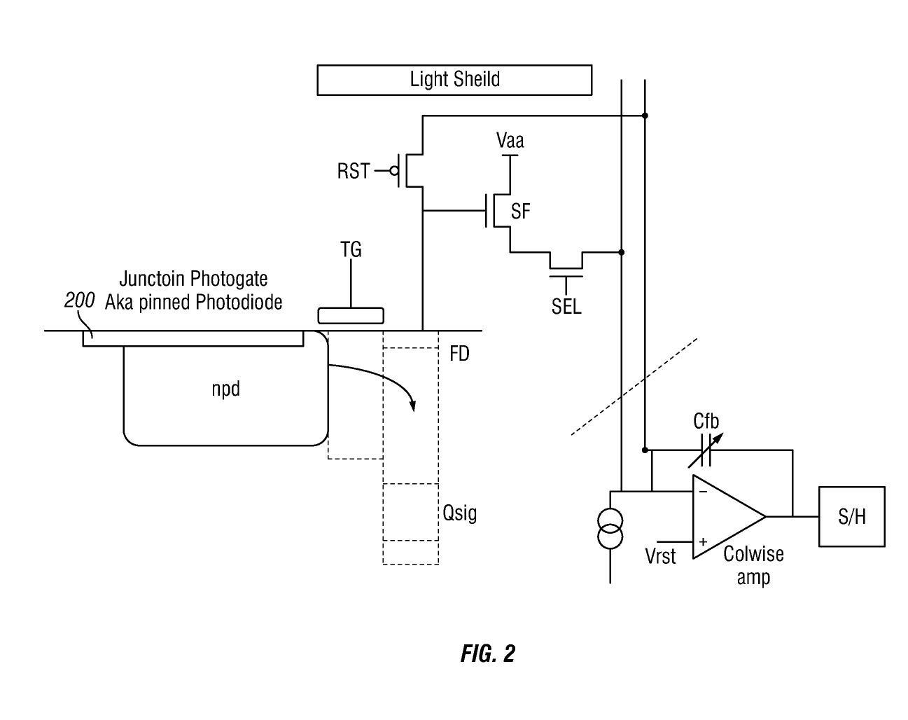

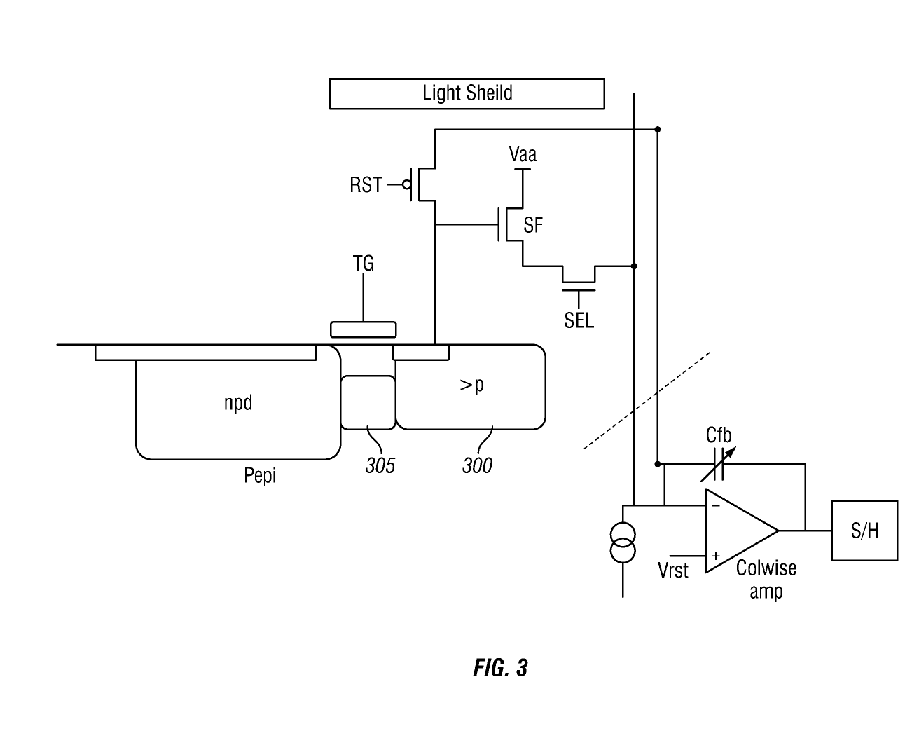

An alternative embodiment shown in FIG. 2 may use a junction photogate 200 as the photoreceptor junction photogate, also known as a pinned photodiode, since this photogate is pinned at the substrate potential.

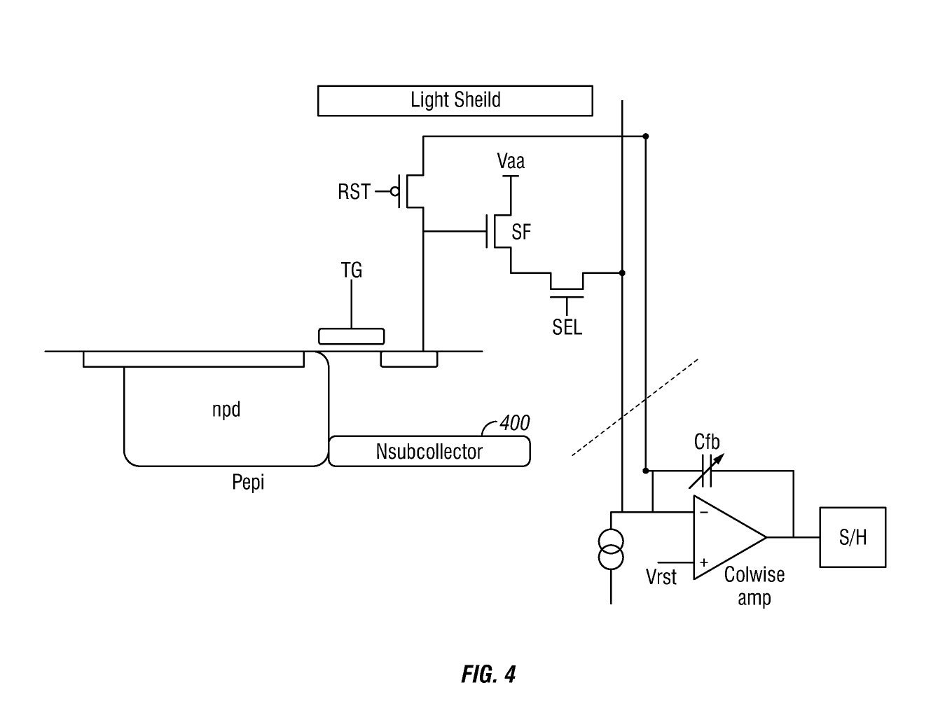

The floating diffusion storage node 120 is protected against incident photons by a light shield 170 which can be placed over all areas which might receive light. However, the storage node may still be susceptible to carriers which are generated elsewhere that diffuse to its vicinity. Hence, to further protect the floating node 120, a sub collector n region 400 as shown in FIG. 4 can be used to redirect and collect errant photons. This region may also be tied to the photogate well.

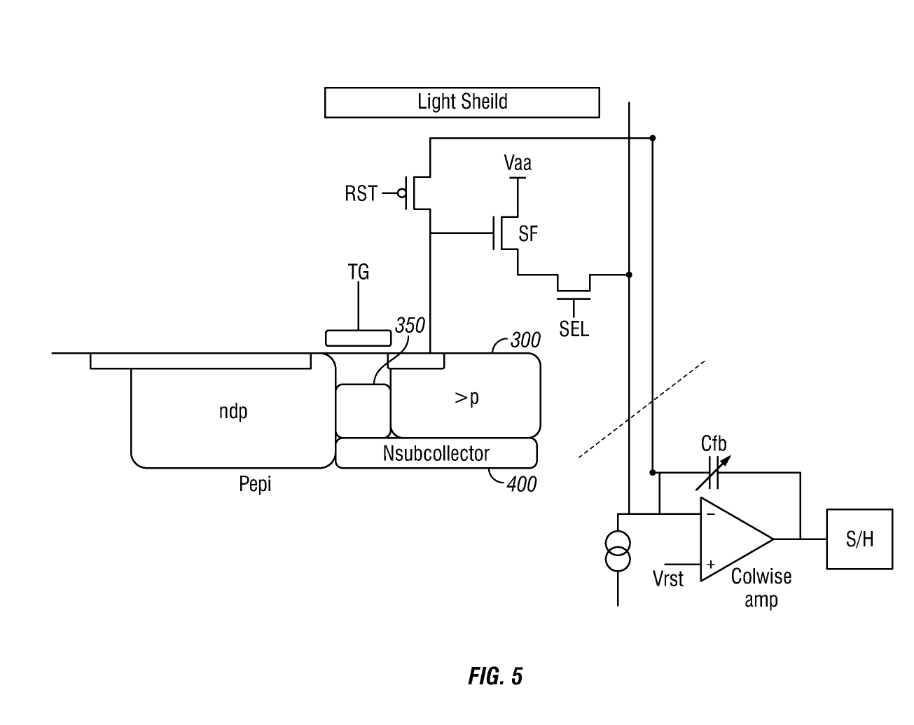

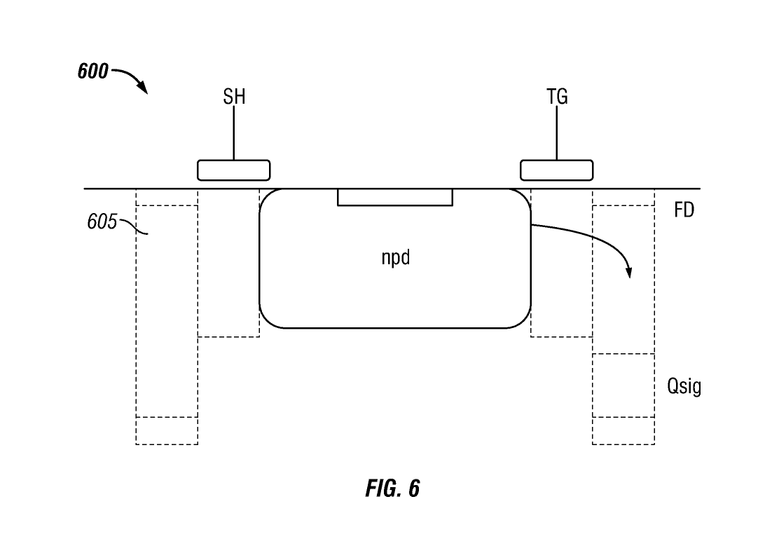

In another embodiment, a heavier p level doping area 300 can be used that will create an energy barrier 305 to reflect the errant photo carriers. The barrier should typically be larger than KT/q. In another embodiment, both of these techniques may be used together as shown in FIG. 5.

FIG. 6 illustrates how the shutter period can be controlled by resetting the photo site sometime during the read-out. The floating diffusion node is reset with feedback in this embodiment. Reset may hence be carried out using a secondary shutter gate 600, which dumps the charge to a well 605. Another embodiment can use a vertical overflow drain can be used. The secondary shutter gate may be easier to implement, but may add additional pixel area. The vertical overflow drain requires more process complexity.

Although only a few embodiments have been disclosed in detail above, other embodiments are possible and the inventors intend these to be encompassed within this specification. The specification describes specific examples to accomplish a more general goal that may be accomplished in another way. This disclosure is intended to be exemplary, and the claims are intended to cover any modification or alternative which might be predictable to a person having ordinary skill in the art. For example, other components can be used. While the above describes operation in charge mode, it should understood that this system can operate in current mode or any other mode. Also, while this describes MOS pixel sensors, these techniques can be used with other sensors.

Another embodiment may use similar techniques to those described herein, along with backside illumination.

Any of the embodiments described herein may reverse the doping types relative to the types described.

These embodiments may be located in a semiconductor substrate, whose top or bottom surface receives the illumination. That illumination receiving surface may also have color filter arrays, to allow full color operation, and may have microlenses and other optical parts.

In addition to the circuits described herein, this integrated circuit may include many other conventional parts, including A/D converters and noise reduction parts (such as correlated double sampling circuits), latches, counters, decoders, row and/or column drivers, and signal conditioning circuits.

Also, the inventors intend that only those claims which use the words “means for” are intended to be interpreted under 35 USC 112, sixth paragraph. Moreover, no limitations from the specification are intended to be read into any claims, unless those limitations are expressly included in the claims.

What is claimed is:

1. An image sensor, comprising:
a photoreceptor;
a diffusion, which is separated from said photoreceptor, and operative to store charge which has been generated in said photoreceptor;
an active reset circuit, which uses feedback from sampling said diffusion to actively reset said diffusion to a specified reset level, and which also produces a signal indicative of an amount of said feedback, and uses said signal indicative of said amount of feedback as a signal indicative of an output of said photoreceptor.

2. A sensor as in claim 1, wherein said photoreceptor is formed from an MOS transistor.

3. A sensor as in claim 1, wherein said photoreceptor is pinned to substrate potential.

4. A sensor as in claim 1, wherein said active reset circuit samples a value from said diffusion that represents an output from the photoreceptor, and produces said feedback signal at a level that brings said feedback level to said reset level.

5. A sensor as in claim 4, further comprising a circuit component that monitors said feedback level which equalizes to said reset level.

6. A sensor as in claim 5, wherein said feedback level is an amount of charge, and said circuit component that carries out said monitoring includes a capacitor.

7. A sensor as in claim 5, wherein said feedback level is sampled as an output value of the image sensor for a specified period.

8. A sensor as in claim 5, wherein said output value is produced during a time while said photoreceptor is integrating for a subsequent image acquisition period.

9. A sensor as in claim 6, further comprising a reset structure which resets said capacitor.

10. A sensor as in claim 6, further comprising a control line which connects said capacitor to said photoreceptor, to use said capacitor for additional integration capability of said photoreceptor.

11. A sensor as in claim 1, further comprising a light shield, which blocks said diffusion against receiving light.

12. A sensor as in claim 11, further comprising an additional electronic structure which prevents diffusion of stray photo carriers into said diffusion.

13. A sensor as in claim 12, wherein said additional electronic structure is a doped P. layer which creates a barrier player against light diffusion.

14. A sensor as in claim 12, wherein said additional electronic structure is a sub collector area.

15. A sensor as in claim 13, wherein said additional electronic structure is a sub collector area.

16. A sensor as in claim 1, further comprising a gate which controls reset of said charge.

17. A sensor as in claim 1, further comprising a reset switching transistor, which is switched on to connect said feedback level to said diffusion, and switched off to leave said diffusion floating.

18. A sensor as in claim 1, further comprising a charge transconductance amplifier as part of said active reset circuit.

19. An method, comprising:
receiving photogenerated charge;
storing said photogenerated charge in an area that is separated from said receiving;
actively resetting said area by sampling said area, and using feedback from sampling said diffusion to actively reset said area to a specified reset level; and
using a signal indicative of an amount of said feedback, to represent an output of said photoreceptor.

20. A method as in claim 19, wherein said receiving comprises receiving charge in an MOS transistor.

21. A method as in claim 19, wherein said receiving comprises receiving charge in a photoreceptor that is pinned to substrate potential.

22. A method as in claim 19, wherein said using feedback comprises monitoring said feedback level.

23. A method as in claim 22, wherein said feedback level is an amount of charge.

24. A method as in claim 22, wherein said feedback level is sampled as an output value for a specified period.

25. A method as in claim 24, wherein said output value is produced during a time while said photoreceptor is integrating for a subsequent image acquisition period.

26. A method as in claim 19, wherein said signal indicative of feedback is a charge mode signal.

27. A system, comprising:
a photoreceptor, which stores charge indicative of photo generated charge;
a floating diffusion, which receives a transfer of said charge;
a charge mode device, which actively resets said floating diffusion to a specific level by outputting an amount of charge that resets said diffusion; and
a charge accumulation part, which samples an output of said floating diffusion during said actively resets.
